(19) United States
(12) Patent Application Publication
(10) Pub. No.: US 2023/0335587 A1
(43) Pub. Date: Oct. 19, 2023

(54) LEDGE-DIRECTED EPITAXY OF CONTINUOUSLY SELF-ALIGNED SINGLE-CRYSTALLINE NANORIBBONS OF 2D LAYERED MATERIALS AND METHOD

(71) Applicant: KING ABDULLAH UNIVERSITY OF SCIENCE AND TECHNOLOGY, Thuwla (SA)

(72) Inventors: Vincent Chun-Chih TUNG, Emeryville, CA (US); Areej Alhussien ALJARB, Thuwal (SA)

(21) Appl. No.: 18/025,677

(22) PCT Filed: May 3, 2021
(86) PCT No.: PCT/IB2021/053692

§ 371 Date: Mar. 10, 2023

Related U.S. Application Data
(60) Provisional application No. 63/080,305, filed on Sep. 18, 2020.

(51) Int. Cl. H01L 29/06; H01L 29/778; H01L 21/02; H01L 29/66

(52) U.S. Cl. CPC H01L 29/0665; H01L 21/02414; H01L 21/02433; H01L 21/02568; H01L 21/02664; H01L 29/66969; H01L 29/778

(57) ABSTRACT

A transistor includes a substrate, an oxide layer located over the substrate, a nanoribbon located over the oxide layer, and first and second electrodes formed around the nanoribbon. The nanoribbon has an aspect ratio of a length over a thickness equal to or larger than 5,000.

### CROSS-REFERENCE TO RELATED APPLICATIONS

This application claims priority to U.S. Provisional Pat. Application No. 63/080,305, filed on Sep. 18, 2020, entitled “LEDGE-DIRECTED EPITAXY OF CONTINUOUSLY SELF-ALIGNED SINGLE-CRYSTALLINE NANORIBBONS OF 2D LAYERED MATERIALS,” the disclosure of which is incorporated herein by reference in its entirety.

### BACKGROUND

### Technical Field

Embodiments of the subject matter disclosed herein generally relate to dense arrays of continuous, self-aligned, monolayer and single-crystalline nanoribbons, and more particularly, to a ledge-directed epitaxy (LDE) of such nanoribbons.

### Discussion of the Background

Planar transistors have been used for myriad generations with size and voltage scaling to enhance performance and save cost, following the well-known Moore’s Law. Innovation of fin field-effect transistor (Fin-FET) architecture was the solution and rendered further device scaling possible. Unfortunately, the short-channel effect ultimately limits the Fin-FET scaling. A wave of revolutionary design in FET architecture with superior gate control over the channel then began to take hold. This emerging technology uses a stacked sheet architecture, which typically consists of multi-stacked semiconducting nanosheets with surrounding gate metals, and demonstrates better short-channel control and thus holds the promise to extend Moore’s Law.

Aligned arrays of single-crystal, monolayer two-dimensional (2D) transition metal dichalcogenide (TMD) nanoribbons with high aspect ratios, which represent the ultimate limit of miniaturization in the vertical dimension, are therefore very attractive in this context. Specifically, the ability to achieve single crystallinity and electrical uniformity throughout the entirety of the 2D TMD nanoribbons, which are the key metrics of enabling batch production FET arrays, would allow a very high degree of electrostatic control at very low power consumption. Synthetic strategies towards TMD nanoribbons have been reported to individually achieve control of layer number, single crystallinity, self-alignment and dimensionalities [1] to [3]. However, the shortage of a manufacturing route towards TMD nanoribbons that synergistically combines all the aforementioned properties remains a major challenge.

It is known that the lattice orientation of the 2D TMDs can be guided by substrates through lifting the energy degeneracy of the 2D TMD-substrate van der Waals (vdW) system. It is known that the lateral docking of 2D hexagonal boron nitride (hBN) seeds to the atomic step edges of Cu (111) substrates pre-dominates over the vertical vdW registry of hBN on Cu, ensuring the mono-orientated nucleation and thus achieving the growth of a single-crystal 2D hBN film [4]. These demonstrations of synthesizing the uniform monolayer 2D TMD films with single crystallinity highlight that the selection of the substrate (for example, thermodynamics) and the growth parameter control (for example, kinetics) contribute to the success of making the nanoribbons with the desired properties.

However, the existing methods are not easily scalable to the wafer-scale, which is required for large scale manufacturing of such devices. Thus, there is a need for a new method of making single-crystalline nanoribbons of 2D layered materials that overcomes the above noted limitations of the existing methods.

### BRIEF SUMMARY OF THE INVENTION

According to an embodiment, there is a transistor that includes a substrate, an oxide layer located over the substrate, a nanoribbon located over the oxide layer, and first and second electrodes formed around the nanoribbon. The nanoribbon has an aspect ratio of a length over a thickness equal to or larger than 5,000.

According to another embodiment, there is a method for making nanoribbons, and the method includes providing a single-crystal based substrate that exhibits cleavage, wherein the substrate has plural ledges and plural bases that extend between the plural ledges, heating first and second precursors at different temperatures, growing domains made of the first and second precursors, starting from each ledge of the plural ledges, and extending over the plural bases, and forming plural nanoribbons, each nanoribbon of the plural nanoribbons extending from a single ledge over one or two bases. The nanoribbon is continuous, single-crystalline, and self-aligned.

According to still another embodiment, there is a method for transferring a nanoribbon from a first substrate to a second substrate, and the method includes growing plural nanoribbons on a single-crystal based substrate, which exhibits cleavage, wherein the substrate has plural ledges and plural bases that extend between the plural ledges, forming a layer of polydimethylsiloxane over the nanoribbons, removing the layer of polydimethylsiloxane and the nanoribbons from the single-crystal based substrate, transferring the layer of polydimethylsiloxane and the nanoribbons onto a target substrate, and forming source and drain electrodes over the nanoribbons to form an electronic device.

### BRIEF DESCRIPTION OF THE DRAWINGS

For a more complete understanding of the present invention, reference is now made to the following descriptions taken in conjunction with the accompanying drawings, in which:

FIGS. 1A to 1H illustrate a method for forming nanoribbons on plural ledges of a single-crystal material by epitaxy deposition;

FIG. 2 illustrates plural ledges of the single-crystal material and their chemical configurations;

FIGS. 3A to 3D illustrate the growing of MoS₂ domains at the ledges of the single-crystal substrate, until forming MoS₂ nanoribbons;

FIG. 4 illustrates a process of controlling a size of the nanoribbons by controlling a growing temperature;

FIG. 5 is a polar plot of a polarization-resolved second harmonic generation intensity and the backscattered laser light as a function of detection angles;

FIG. 6A is a cross-sectional microscopy image of a MoS₂ nanoribbon grown on β—Ga₂O₃ (100) substrate, and FIG. 6B is a cross-sectional microscopy image of the β—Ga₂O₃ (100) substrate taken normal to the [010] direction to reveal a Ga atom missing from the ledge;

FIG. 7A is a computer-generated atomic model showing one nucleation event on a (-201) ledge with orientation toward 0°, and FIG. 7B is a computer-generated atomic model showing another nucleation event on the (-201) ledge with orientation toward 180°;

FIG. 8 shows the potential energy surface mapping derived from the density function theory calculations;

FIG. 9 shows the hyper-spectral PL mapping of the nanoribbons, which display a uniform wavelength distribution along the two parallel-aligned MoS₂ nanoribbons;

FIG. 10 shows the configuration of a transistor having the nanoribbon as a channel material;

FIG. 11 shows an array of transistors that share the same nanoribbon as the channel material;

FIG. 12A is a bar chart that shows statistics taken from measurements across the entire MoS₂ nanoribbons, with the various characteristics being almost identical for five different transistors, and FIG. 12B shows the histogram of field-effect mobility and on/off ratios measured for 100 transistors made of different batches of nanoribbons;

FIG. 13 shows the transfer characteristic of the MoS₂ nanoribbons for a field-effect transistor;

FIGS. 14A to 14C illustrate location selective PL spectra taken across the MoS₂ nanoribbons;

FIG. 15A shows the low-temperature PL spectra for exfoliated MoS₂ material and FIG. 15B shows the same spectra for the MoS₂ nanoribbons grown with a novel method discussed herein;

FIG. 16 illustrates plural nanoribbons formed on a common substrate with the nanoribbons having different chemical compositions and/or electrical conductivities;

FIG. 17 is a flow chart of a method for transferring nanoribbons from one substrate to another substrate; and

FIG. 18 is a flow chart of a method for growing the nanoribbons at ledges of a single-crystal substrate.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to MoS₂ nanoribbons that are grown on plural ledges of a single-crystal Ga₂O₃ substrate. However, the embodiments to be discussed next are not limited to these two materials, but other materials that have similar properties may be used.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, there is a novel method that employs epitaxial growth of single-crystalline and aligned TMD nanoribbons via LDE-assisted chemical vapour deposition (CVD) that relies on the thermodynamic control of the TMD seeding orientation in conjunction with the kinetic control of the growth direction. Because the novel LDE growth is directed by the combination of the ledge sites and the surface-diffusion-limited pathway, which is specific to the Ga₂O₃ substrates, the use of this method is not limited to the MoS₂—Ga₂O₃ combination discussed next. Instead, the method could be generalized for producing various TMD nanoribbons, including n-(MoS₂), p-(WSe₂) and even lateral n-(MoS₂)-p-(WSe₂)-n-(MoS₂) junctions with precise single crystallinity, alignment and monolayer controls over a micro- to centimeter scale. While the TMD nanoribbons with lateral heterostructures have been recently reported by vapour-liquid-solid growth [2], such a process only allows the growth of heterostructures with either different metals or chalcogen atoms, thus making it challenging for the creation of p-n heterostructures or even n-p-n multi-heterostructures.

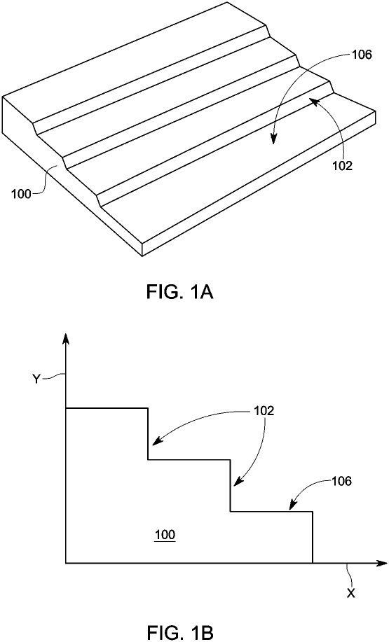

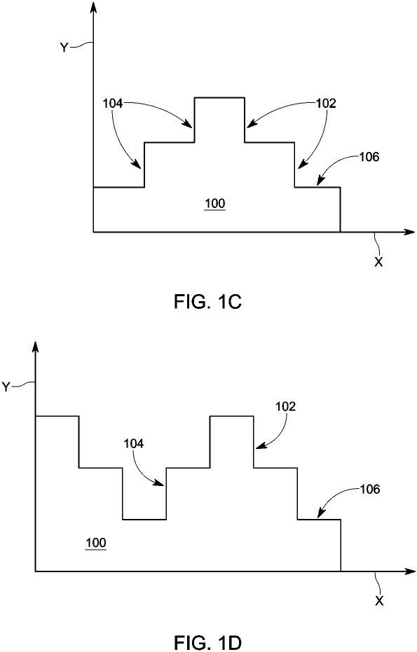

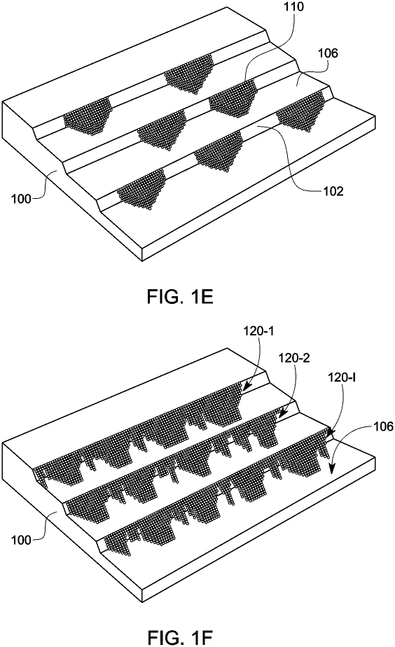

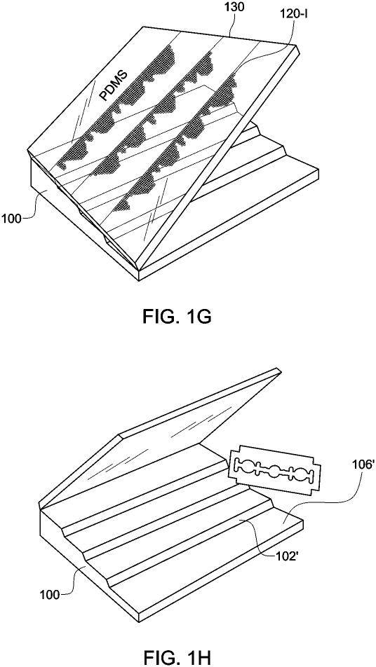

The method of growing the monolayer MoS₂ nanoribbons along the intrinsically aligned ledges on a β—Ga₂O₃ (100) substrate, which can be reused after a facile mechanical exfoliation, is now discussed with regard to the figures. FIG. 1A illustrates a single-crystal β—Ga₂O₃ (100) substrate 100 with exposed ledges 102, which are separated by bases 106. Note that the term “single-crystal” means in this context that the entire substrate 100 is a single crystal. Further, the term (100) indicates a specific orientation of a crystallographic plane that is associated with the single-crystal substrate 100. Furthermore, the single-crystal β—Ga₂O₃ (100) substrate 100 exhibits cleavage, which is defined herein as a material that splits along smooth planes. As shown in FIG. 1B, the substrate 100 has plural ledges 102, which are disposed like stairs, at different heights relative to a base of the substrate. For each ledge 102, there is a corresponding horizontal surface 106, which is called herein a “base.” FIG. 1C shows another possible configuration of the substrate 100, with ledges 102 and 104 being located next to steps 106, and facing opposite directions. In this configuration, as discussed later, the two ledges 102 and 104 have different orientations. FIG. 1D shows yet another configuration in which the ledges 102 and 104 are randomly distributed. It is noted that the single-crystal β—Ga₂O₃ (100) can have the ledges 102 and 104 distributed in any configuration. Although the ledges 102 and 104 appear to be perpendicular to the horizontal axis X in FIGS. 1B to 1D, it is noted that the ledges make an obtuse angle with the horizontal axis. The number of ledges per substrate 100 is between 20 and 10,000.

FIG. 1E shows the nucleation of the MoS₂ seeds (or flakes) 110 with a preferred orientation taking place on the ledges 102/104 of the β—Ga₂O₃ substrate 100. It is noted that FIG. 1E shows plural seeds 110, all of them starting at the ledges 102 or 104, and all of them extending over the bases 106. These seeds grow into plural domains over the corresponding bases 106. Thus, the bases 106 provide a support for the TMD growing, which eventually will result in the nanoribbons. FIG. 1F shows the aligned MoS₂ domains merging into continuous nanoribbons 120-I, with I being an integer that corresponds to the number of ledges. As the nanoribbons grow from the ledges and over the bases, they will have the same surface shape as the surface of the bases. After fully growing the MoS₂ nanoribbons 120-I, they can be peeled off from the β—Ga₂O₃ (100) substrate 100 as shown in FIG. 1G, and readily transferred to arbitrary substrates via a process assisted by polydimethylsiloxane (PDMS) 130. The substrate 100 may be then (mechanically) exfoliated, as shown in FIG. 1H, to remove the existing ledges and bases and form new ledges 102′ and bases 106′, so that the substrate 100 can be reused for another round of growth, i.e., the process can start again as shown in FIG. 1A, with the same substrate 100.

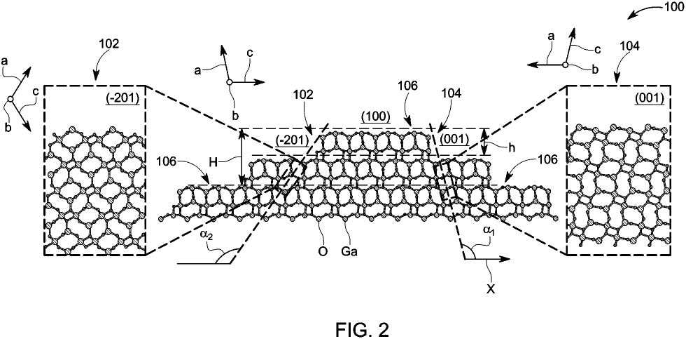

Intrinsically, the (100) plane of the freshly exfoliated β—Ga₂O₃ substrate 100 exhibits atomically sharp steps with a step height h of about 6 Å (half unit cell). These steps trend up and down across the entire β—Ga₂O₃ substrate 100 as illustrated in FIGS. 1B to 1D, resulting in the two sets of structurally equivalent but crystallographically inverted ledges 102 and 104, namely (-201) and (001), respectively. FIG. 2 shows the two ledges 102 and 104 and their crystallographic structure and also the base 106 having the (100) crystallographic structure. It is noted that both the ledge 102 and the ledge 104 have the step h of half unit cell, and not the step H of the full unit cell. FIG. 2 also shows that both ledges 102 and 104 make an obtuse angle with the horizontal axis X, and the angle α₁ of the ledge 104 is larger than the angle α₂ of the ledge 102. Thus, the plural ledges that are found on the substrate 100 include different first and second ledges 102 and 104, with the first ledge extending in the (-201) plane and the second ledge extending in the (001) plane, while the bases 106 extend in the (100) plane.

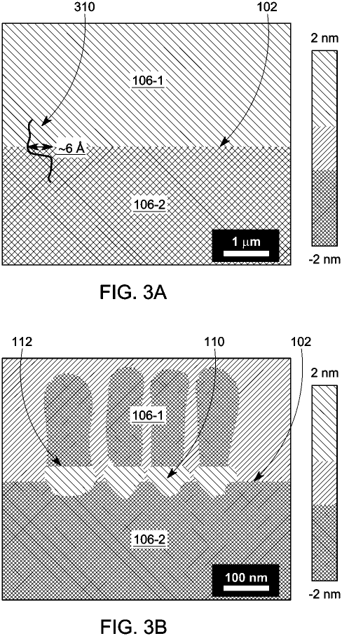

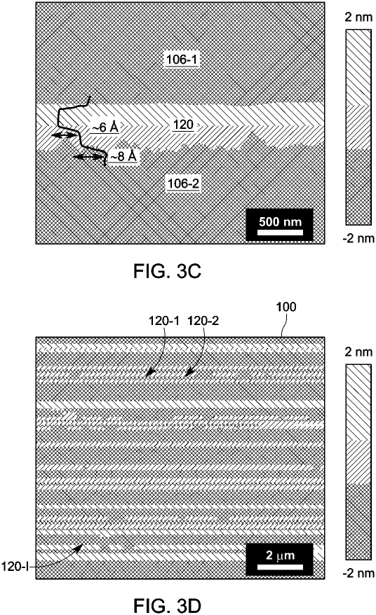

Various stages in the growth of the MoS₂ nanoribbons 120-I are revealed by atomic force microscopy (AFM) in FIGS. 3A to 3D. More specifically, FIG. 3A shows the height profile 310 along the atomic step between two consecutive bases 106-1 and 106-2, which are separated by a ledge 102. It is noted that the height difference between the two consecutive bases 106-1 and 106-2 is about 6 Å. This height depends on the material used for the substrate 100. FIG. 3B shows the seeds growing from the ledge 102, over the bases 106-1 and 106-2. Note that one side 112 of the seeds 110 is very flat, which means that this side is growing from the ledge 102, over the higher base 106-1. As the growing of the seeds progresses, they form domains 110, which start to join each other across the base 106-2, as illustrated in FIG. 3C. It is noted that the domains can also grow toward and over the base 106-1. However, this kind of growth is not desired as the nanoribbons are desired to be as flat as possible. FIG. 3B indicates that unidirectional nucleation of the four MoS₂ domains 110 occurs at the ledge 102. The edges of these triangular MoS₂ domains 110 stay parallel to the well-defined step edge, whereas the vertices point towards the lower base 106-2. Meanwhile, it is observed that the nucleation density of the oriented MoS₂ domains along both the (001) and (-201) ledges is overwhelmingly higher than that on the flat bases or terraces 106, where only a sporadic distribution of randomly oriented MoS₂ flakes (the orientation varies between 0°, 90°, 180° and 270° owing to the symmetry of the β—Ga₂O₃ substrate, which is monoclinic in nature) can be spotted. The observation of the unidirectional MoS₂ flakes 110 on the atomically textured, single-crystalline β—Ga₂O₃ (100) substrate 100 indicates the existence of an energetically minimized MoS₂-β—Ga₂O₃ ledge configuration, thus forming the basis for subsequent coalescence into continuous nanoribbons with single crystallinity. Indeed, aligned and mono-oriented MoS₂ domains 110 grow by successive addition from the surrounding precursors and ultimately merge into a MoS₂ nanoribbon 120 as the LDE approaches completion, as shown in FIG. 3C. The resulting MoS₂ nanoribbons 120 exhibit a uniform step height of about 8 Å relative to the corresponding base 106-2, which is characteristic of the monolayer MoS₂. In one application, this step height corresponds to the thickness of the nanoribbons. Thus, the thickness of the nanoribbons is about 1 nm, with a preferred value of 0.8 nm.

Another unique capability of the LDE method is the controlled nucleation and unidirectional growth of ordered arrays of MoS₂ nanoribbons 120-I at the atomic scale, e.g., up to a centimeter long and with an aspect ratio larger than 5,000, where the aspect ratio is defined as the ratio between the length of the nanoribbon and its thickness. Note that a width of the nanoribbons formed with the LDE method is not larger than 1 µm. In one embodiment, the width of the nanoribbon is between 50 and 700 nm. In one application, the width of the nanoribbon is about 70 nm. Images of the AFM and scanning electron microscopy (SEM) collectively demonstrate the growth of dense arrays of globally aligned, continuous MoS₂ nanoribbons 120-I enabled by LDE over the entire β—Ga₂O₃ (100) substrate 100, as shown in FIG. 3D.

In parallel, the innate step edges, which are present on the monolithic β—Ga₂O₃ (100) crystals 100, have a propensity to cleave parallel to the (100) plane and (001) planes by a half unit cell. This is the result of the unique octahedral arrangements of the Ga atoms, which are parallel to the (010) plane. Consequently, the newly exfoliated (100) plane of the β—Ga₂O₃ substrate retains atomically clean, ordered and spatially distributed step edges with half-unit-cell ledges 102′, 104′, as shown in FIG. 2. Photoluminescence (PL) measurements taken on different batches of the MoS₂ nanoribbons grown on the repeatedly exfoliated β—Ga₂O₃ (100) substrate 100 reveals neither changes in full width at half maximum (FWHM) nor a shift in the PL peaks, making possible the continuous and reliable batch production of high-quality MoS₂ nanoribbons 120. This peeling feature is particularly appealing as the ability to reuse the β—Ga₂O₃ substrates eliminates the needs for a time-consuming and often laborious lithography process.

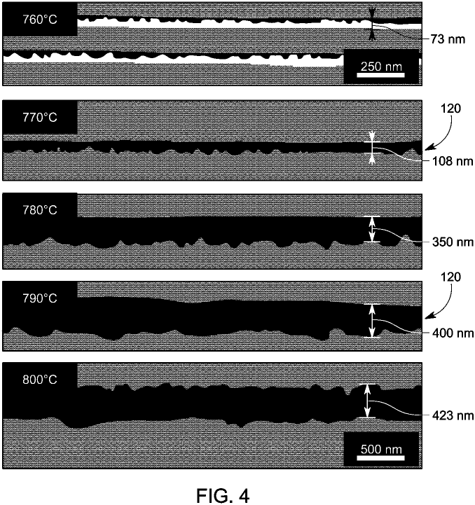

While all the aligned MoS₂ flakes 110 interlock in the same way and have identical orientation, the atomic structure of the β—Ga₂O₃ (100) substrate has a profound implication on the geometric shapes of the edges of the MoS₂ nanoribbons 120. Unlike the MoS₂ flakes grown on a symmetrical substrate, the MoS₂ flakes grown on the β—Ga₂O₃ (100) substrate 100 exhibit asymmetrically shaped edges, that is, smooth and zigzag-shaped edges, which is visible in FIG. 3C. Away from the well-defined ledges 102/104, the extremities of the merged MoS₂ flakes 110 are permitted to grow without any external constraint. The edge of the single-crystalline MoS₂ nanoribbons that is furthest from the corresponding ledge assumes a regular zigzag shape, as shown in FIG. 3C. High-angle annular dark-field scanning transmission electron microscopy (HAADF-STEM) images generated by the inventors confirm the zigzag-shaped edges of the nanoribbons. Occasionally, the inventors observed the formation of bilayer MoS₂ nanoribbons. High-resolution (HR) HAADF-STEM images near the edges of the bilayer regions reveal the absence of the Moiré patterns, indicating predominantly 2H stacking orders. Moreover, by controlling the growth temperature and nucleation density, the width of the MoS₂ nanoribbons 120 can be systematically varied between 70 nm and 600 nm, as illustrated in FIG. 4, for which the width likely can meet the requirement for stacked sheet transistor applications. A further decrease in width, for which fundamental confinement effects may arise, such as changes in bandgap and the presence of one-dimensional metallicity, is possible experimentally.

To verify the orientation of the individual flakes 110 and the associated crystallinity of the MoS₂ nanoribbons 120, the LDE MoS₂ nanoribbons 120 were characterized by second harmonic generation (SHG) micro-spectroscopy and dark-field (DF) STEM. It is known that polarization-resolved SHG is sensitive to crystal orientation, and the intensity profile map can be used as a descriptor for verifying spatial orientations of the merged flakes within the coalesced nanoribbons 120. The SHG intensity map (not shown) taken for three horizontally aligned MoS₂ nanoribbons with perpendicular polarization demonstrate that all three MoS₂ nanoribbons have homogenous SHG intensities except for a few nodes along the direction of laser irradiation. The discontinuity of the SHG intensity is the result of the rarely observed multilayer MoS₂ seeds interspersed between the continuous MoS₂ nanoribbons, seen by comparison of AFM images. The homogeneity of the SHG intensity proves that each nanoribbon indeed includes MoS₂ flakes with a single orientation. Furthermore, the inventors deduced the angles between the laser polarization direction and the nearest armchair direction via the equation θ = (⅓) tan⁻¹

$$\sqrt{{I}_{x} / {I}_{y}} .$$

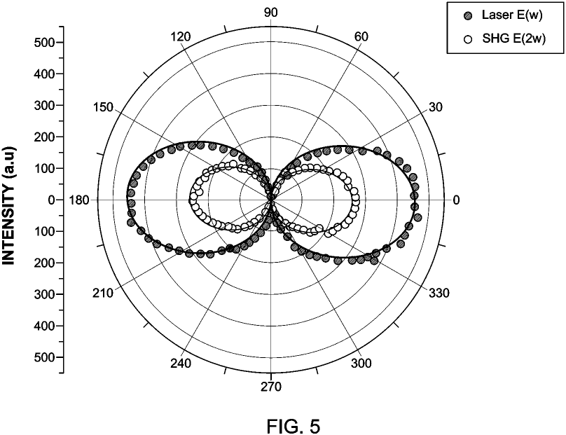

Jlxlly. In this light, the intensity map (not shown) that spatially resolves the angle distribution derived from compiling the simultaneously detected Iₓ and I_{y} SHG intensity, reveals a uniform yet narrow angular distribution of about 2°. The orientation of the zigzag direction is further confirmed by drawing comparisons of the polarization-resolved SHG intensity between the MoS₂ nanoribbons and the reflected laser from the substrate. As indicated in the polar plot of FIG. 5, the MoS₂ flakes 110 with mirror domains of 0° and 180° orientations are angularly equivalent in terms of the SHG intensity. The SHG can help to characterize the nanoribbons in a large area, but further distinguishing such mirror domains requires other methodologies.

It is known that a variation in the crystallographic orientations disturbs the structural continuity, i.e., the formation of grain boundaries. This disruption manifests signs of polycrystalline domains in annular dark-field (ADF) STEM on the nanometer length scale. Mirror domains of 0° and 180° can therefore be determined on the basis of convergent beam electron diffraction patterns (not shown). ADF-STEM images (not shown) confirm the absence of mirror domains and thus, the existence of crystallographic continuity of the LDE MoS₂ nanoribbons 120 on the micrometer length scale. The studied nanoribbon 120 consists of more than twenty mono-oriented flakes 110, and all the ADF-STEM images (not shown) exhibit crystallographically coherent domains with no visible grain boundaries, confirming the single-crystal nature of the generated LDE MoS₂ nanoribbons 120. Other characterizations, including SEM images, corresponding PL mapping of the characteristic excitonic direct gap emission of the monolayer MoS₂ 120 and signatures from the Raman spectroscopy, prove the structure continuity and crystallographic coherence of the chemical states of MoS₂ nanoribbons 120.

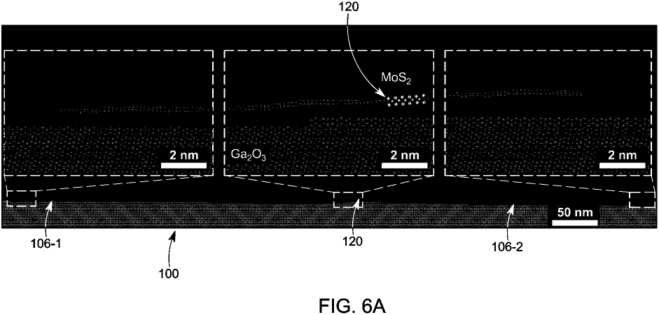

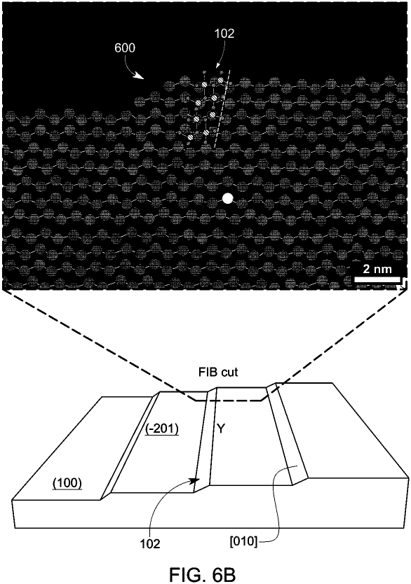

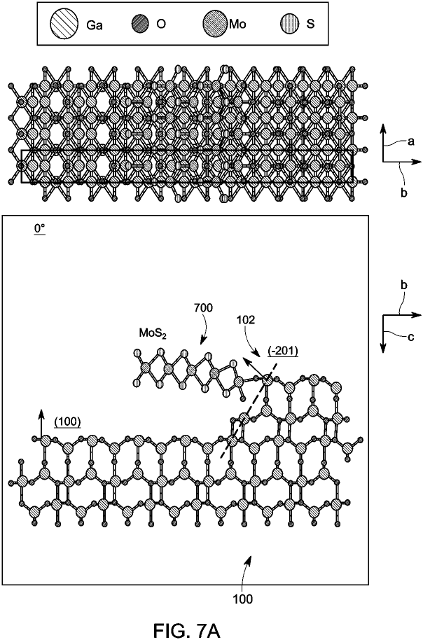

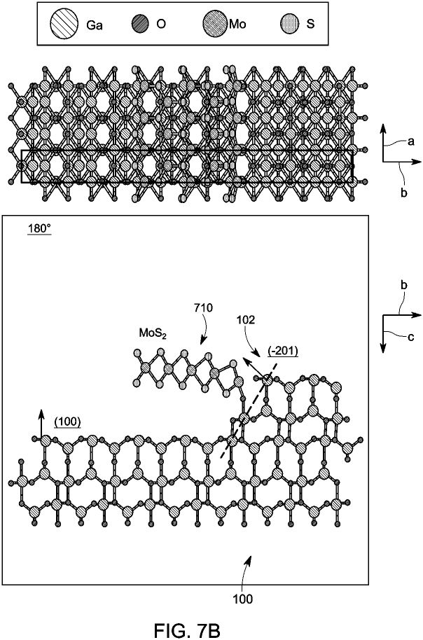

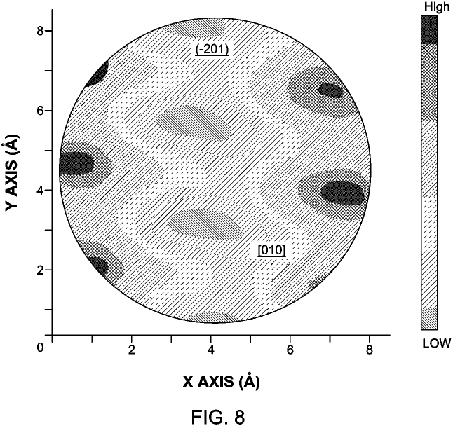

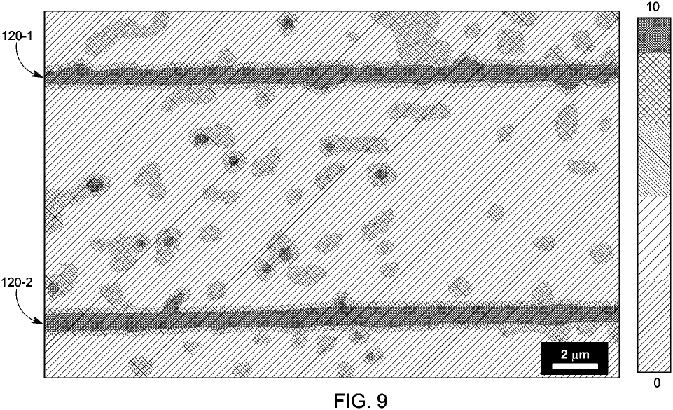

To understand the preferred nucleation at the ledge 102/104 and the controlled growth along the base 106 of the β—Ga₂O₃ substrate 100, the inventors generated the cross-sectional HAADF HR-STEM images shown in FIGS. 6A and 6B to provide the atomically resolved structures of both the MoS₂ nanoribbon 120 and the underlying β—Ga₂O₃ (100) substrate 100. Focused ion beam (FIB) was performed in the transverse direction of the MoS₂ nanoribbon 120, perpendicular to the [010] of the β—Ga₂O₃ substrate. The atomic structures of the MoS₂ nanoribbons 120 are divided into three regions, based on their location, namely: (i) bottom base or terrace 106-1, (ii) ledge 102, and (iii) top terrace 106-2, allowing the inventors to elucidate the relationship between the epilayer and the growth substrate. In agreement with the AFM image shown in FIG. 3B, the region (ii), i.e., the center segment of the nanoribbons 120, where the nucleation of the aligned, triangular seeds takes place, is found to lie above the (-201) ledge 102 of the β-Ga₂O₃ substrate, which is shown in more detail in FIG. 6B. This preferred alignment of the triangular seeds reveals that the (-201) ledge 102 may represent the preferential nucleation site with the local energetic minimum. With this assumption, the inventors examined the effect of the preferred nucleation sites along the (-201) edges through constructing a cross-sectional atomic model for the β—Ga₂O₃ (100) substrate. Here, the β—Ga₂O₃ (100) substrate 100 has a monoclinic structure with lattice constants of a = 3.037 Å, b = 5.798 Å and β = 103.8°. Two possible nucleation cases are proposed and their binding energies were calculated: (1) case A, where a Ga atom 600 is notably missing from the vicinal (-201) ledge 102 (see FIGS. 6B and 7A); and (2) case B, where Ga atoms remain intact near the (-201) ledge 102 (not shown). In case A, the MoS₂ molecules 700 with 0° orientation and the molecules 710 with 180° orientations are used as nuclei and are intentionally placed in the vicinity of the (-201) edges on the β—Ga₂O₃ (100) substrate 100, as schematically represented in FIG. 7A (0° orientation) and 7B (180° orientation). After relaxation, the inventors found that the MoS₂ molecules 700 with 0° orientation predominately dock at the binding sites of the (-201) ledges 102.

First-principle calculations revealed a drastic difference in the binding energy of about 2 eV relative to that of an inversely orientated MoS2 molecule 710 (180°), thus favoring the mono-oriented growth and therefore the unidirectional alignment. An opposite trend is observed in case B, but for this case, the trend exhibits an energy difference of only about 0.535 eV when the MoS₂ molecules dock to the oxygen at the bottom of the (-201) ledge. Unlike case A where the 0° is the preferred orientation, the preferred orientation in case B is 180°, which will lead to mirror grain boundaries in the ribbons. It is observed that the mono-oriented seeds 110 in the nanoribbons 120 are nucleated following the favorable nucleation case A due to the fact that the Ga vacancies are naturally present near the edge of the steps.

The mechanism suggested by the inventors towards unidirectional nucleation is similar to the recently reported defect-enhanced degeneracy breaking of TMDs [5], but is quite independent due to the difference in spatial arrangement of docking sites, which are randomly distributed and disorganized defect sites, versus spatially ordered and aligned ledge sites. Nevertheless, in [5], the authors observed the reversal of the triangle orientation (that is, 0° becomes 180°) of MoS₂ flakes across a step edge in the hBN substrate under the assumption of a change in the layer polarity of the AA′-stacked hBN. On the contrary, the two energetically equivalent, but crystallographically inverted ledges (-201) 102 versus (001) 104 in this application, were revealed by the DF-STEM and atomic models across the step edges of the β—Ga₂O₃ (100) substrate, thus guiding the alignment of the MoS₂ nuclei in the 0° and 180° orientations, respectively. Once the mono-oriented nucleation approaches completion, the rich sulfur environment not only helps to break the vdW interaction between the aligned MoS₂ seeds and the ledges, but also facilities the growth of the single-crystalline domains 110 to extend beyond both ends of the step edge 102, ultimately merging together into a continuous nanoribbon 120.

It is noted that the growth of individual domains, which strongly depends on the diffusion path, seems to be confined and directed along the ledges of the β—Ga₂O₃ (100) substrate 100. This is very intriguing as the growth of the TMDs on highly symmetric substrates by means of CVD typically results in the omnidirectional diffusion of precursor vapors to the local environment. To verify the origin of this directional diffusion pathway, the inventors performed a potential energy surface (PES) mapping of the (-201) plane 102 of the β—Ga₂O₃ (100) substrate 100 via density function theory (DFT) calculations. As shown in FIG. 8, the surface diffusion kinetics along the [010] direction energetically confine the growth of the MoS₂, thus driving the energetically favorable and directionally modulated growth of the aligned domains into single-crystalline nanoribbons. These findings collectively point towards an entirely novel strategy to synthesize dense arrays of single-crystalline and globally aligned TMD monolayer nanoribbons for device applications.

The success of creating extended, single-crystal MoS₂ nanoribbons 120 is manifested in the uninterrupted, homogenous yet narrow distribution of the signature PL wavelength across the aligned domains, indicating the lack of atomic misfits between merged domains as shown in FIG. 9. Meanwhile, the hyper-spectral PL mapping, which provides a fast, global mapping with high spatial and spectral resolution, does not reveal any sign of the PL quenching typically associated with grain boundaries. Results from conductive (C-) AFM on the MoS₂ nanoribbons 120 directly grown on a semiconducting β—Ga₂O₃ substrate 100 show the similar trend in the representative topography (not shown), and corresponding current maps (not shown). The local point current-voltage (I-V, vertical transport) and current mapping were done by applying a positive bias to the β—Ga₂O₃ substrate while the conductive tip (Pt-Ir) was held at ground. The MoS₂ nanoribbons appear highly conducting relative to the underlying β—Ga₂O₃ substrate, making them clearly visible in the current map. The average current flowing throughout the MoS₂ nanoribbons in the vertical direction is 18 (±2) nA. The point I-V curve measured along the MoS₂ nanoribbons exhibits non-ohmic characteristics that appear symmetric. These measurements provide direct experimental evidence of the undisruptive conductive path throughout the entirety of the MoS₂ nanoribbons.

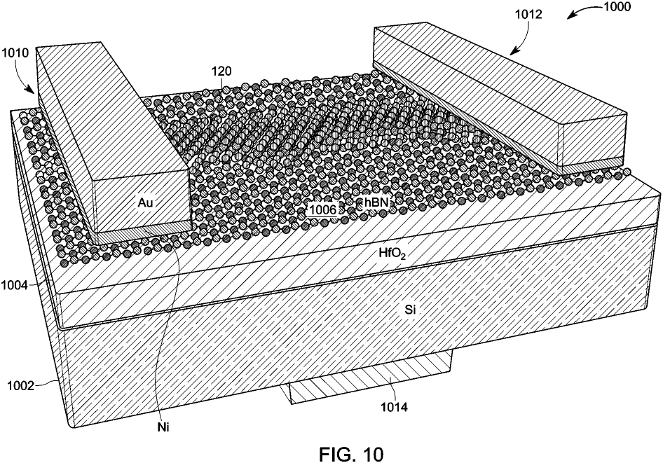

Furthermore, the inventors verified the quality of the MoS₂ nanoribbons 120 by evaluating the field-effect carrier mobility in a bottom-gate transistor configuration 1000, as illustrated in FIG. 10. The transistor 1000 has a substrate 1002, for example, made of Si, on which an oxide film 1004 is formed, for example, HfO₂. To reduce the screening effect from the HfO2 layer 1004, while eliminating the charge scattering and trap sites, a single-crystal hBN monolayer film 1006 is embedded as an interface layer between the HfO₂ layer 1004 and the MoS₂ nanoribbons 120. While FIG. 10 shows a single nanoribbon 120, more than one nanoribbons may be used. The nanoribbon 120 shown in FIG. 10 has a length of 1 mm and was directly implemented as the channel for the transistor. Electrodes 1010 and 1012 are formed over or next to the ends of the nanoribbon 120, and these electrodes act as the drain and source, respectively. The Si substrate may have a corresponding electrode 1014, which may act as the gate of the transistor 1000. In one embodiment, the gate electrode 1014 is not present, and thus, the configuration 1000, can be used as a sensor or detector.

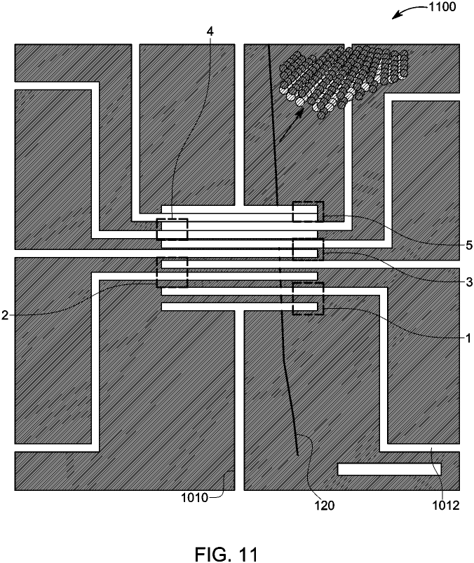

The fabrication of high-performance FET arrays 1100 (see FIG. 11) can take advantage of the direct integration of the LDE MoS₂ nanoribbons 120, which would largely eliminate the needs for the laborious etching of large-area films. Unwanted contamination is found during the process and thus disrupts the transport characteristics. The newly included statistics of transport characteristics taken on an array of FETs, which are directly fabricated on top of the collimated LDE MoS₂ nanoribbons, have two attractive features: the spatial uniformity over a long range, similar to those wafer-scale films synthesized by MOCVD, and excellent transport characteristics on par with those seen in exfoliated counterparts. To this end, arrays 1100 of FET electrode patterns were defined via the e-beam lithography, as shown in FIG. 11, to evaluate the transport characteristics individually and collectively. In this regard, note that FIG. 11 shows five transistors 1-5, each one having a pair of source/drain electrodes 1010 and 1012 (only the electrodes for transistor 1 are labeled). Further, the figure shows a single nanoribbon 120 that extends over all the transistors, i.e., it is shared by the each transistor of the transistors 1-5.

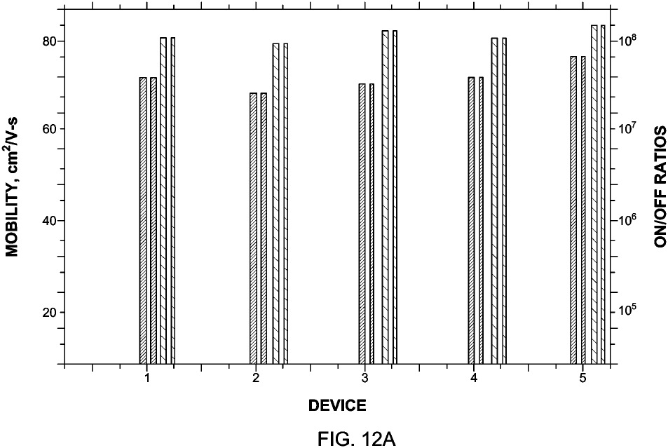

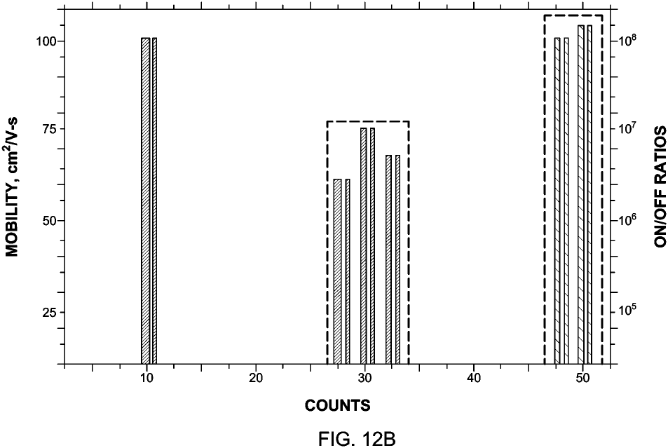

Acknowledging that the measurements discussed herein were performed at room temperature, FIG. 12A shows the field-effect mobility and on/off ratios measured for the five transistors 1-5, having the same MoS₂ nanoribbon 120 and separated by up to 20 µm on a single chip. All five FET transistors exhibit nearly identical behaviors. The figure shows a high field-effect mobility close to 65 cm²N-s and on/off ratios near 108, independent of the channel length and location of the MoS₂ nanoribbons, suggesting the spatial homogeneity of the electrical properties of the MoS₂ nanoribbons across various length scales. FIG. 12B shows the histogram of the field-effect mobility and the on/off ratios measured from 100 FETs made of different batches of MoS₂ nanoribbons. Evidently, single crystallinity throughout the entirety of the MoS₂ nanoribbons is manifested in the very narrow distributions of both the field-effect mobility and the on/off ratios. Occasionally, the inventors have found that the field-effect mobility of the MoS₂ nanoribbons FETs exceeds 100 cm²Λ/-s, with the highest value being 109 cm²/V-s.

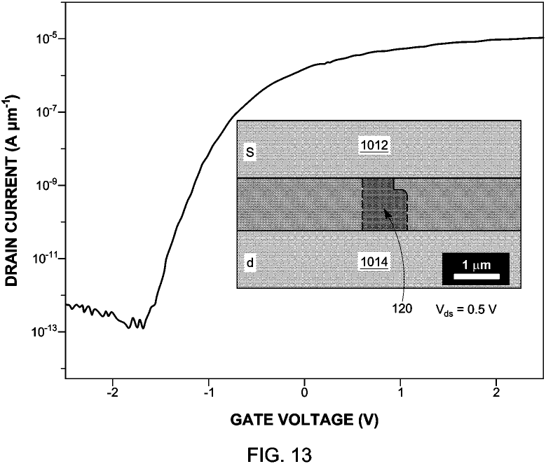

FIG. 13 shows the transfer characteristic of the MoS₂ nanoribbon/hBN field-effect transistor, the inset of the figure showing the SEM of the MoS₂ nanoribbon 120 sandwiched between the source electrode 1012 and the drain electrode 1014. The length and width of the device in this embodiment are 1 µm and 0.39 µm, respectively, giving rise to an averaged electron mobility µ = 65 cm²V-¹s-¹ at a drain voltage V_{ds} of 0.5 V.

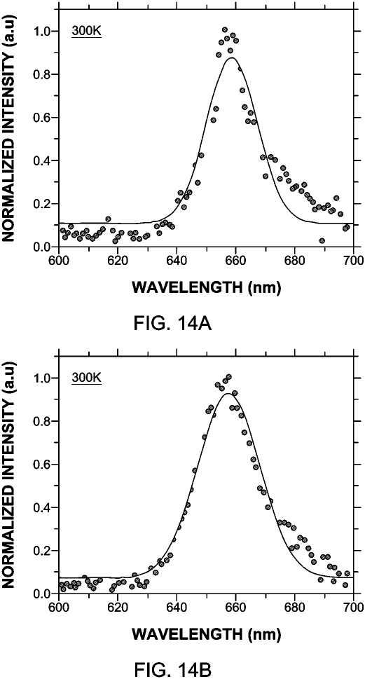

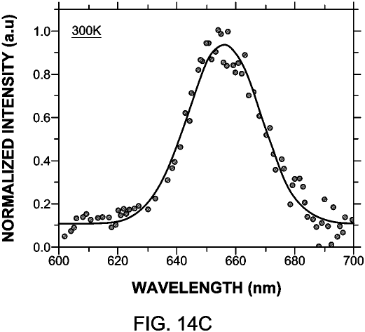

Further, the inventors have conducted DFT calculations on the edge states in the mid-gap of the LDE MoS₂ nanoribbons with armchair (a-NR) and zigzag edges (z-NR). Regardless of their width, the a-NR edge state is always semiconducting with a nearly constant DFT bandgap of about 0.35 eV. By contrast, the z-NR edge state is always metallic. Surprisingly, the abovementioned electrical transport measurements demonstrate the predominant semiconducting characteristics for the LDE MoS₂ nanoribbons. To further investigate the nearly edge-independent electrical transport, the inventors further analyzed the location-selective hyperspectral photoluminescence (PL) and tracked the associated changes in the full width at half-maximum (FWHM), as shown in FIGS. 14A to 14C. Both the PL peak positions and the FWHM did not vary significantly when the focus of laser spot was moved across the MoS₂ nanoribbon (e.g., left edge as shown in FIG. 14A, center region as shown in FIG. 14B, and right edge as shown in FIG. 14C), characteristic of the uniform quality and continuous crystallinity of LDE MoS₂ nanoribbons.

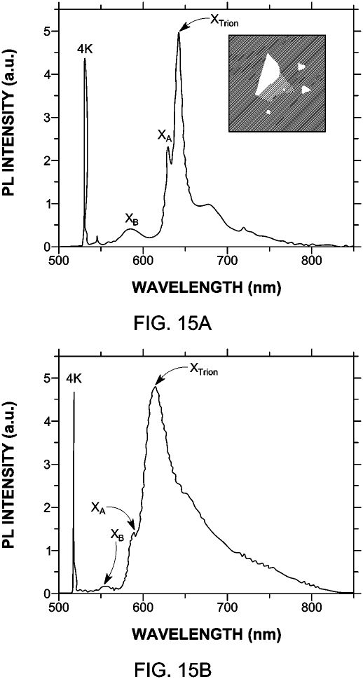

Moreover, the low temperature PL (excitation: 532 nm, power: 200 µW) measured from the LDE MoS₂ nanoribbons shows characteristics (see FIG. 15B) unique to the exfoliated monolayer MoS₂ benchmarks (see FIG. 15A), including comparable PL intensity, a similar level of defects, neutral exciton and trion emission peaks. The almost identical features to those of the mechanically exfoliated MoS₂, with a similar level of defects, further confirms the high-quality of the LDE MoS₂ nanoribbons. The inventors further noted the shift and broadening of the PL peaks from the LDE MoS₂ nanoribbons pertinent to the exfoliated MoS₂ standard, likely due to the interaction with underlying Ga₂O₃. Meanwhile, the CVD grown-MoS₂ typically exhibits a high-density of defects even though these specimens are characterized by the high-to-single crystallinity. As a consequence, the PL induced from defects of CVD-synthesized TMD emerges and outweighs the intrinsic PL at 4 K unless treated chemically or doped electrostatically. The result is the impaired transport property and decreased mobility. The ability of simultaneously preserving single crystallinity and maintaining a low-level of defect density for the LDE MoS₂ nanoribbons during the growth stage has not been reported or achieved elsewhere and thus distinguishes the LDE from the other epitaxy approaches.

The prospect of designing an artificial 2D landscape with an atomically sharp, compositionally diverse, and electrically well-defined interface can complement existing van der Waals (vdW) heterostructures by adding a completely new class of vdW building block (lateral n-p-n heterostructures). This not only can lead to unique electronic, photonic and mechanical properties previously not found in nature, but can open a new paradigm for future material design, enabling unprecedented structures and properties for unexplored territories.

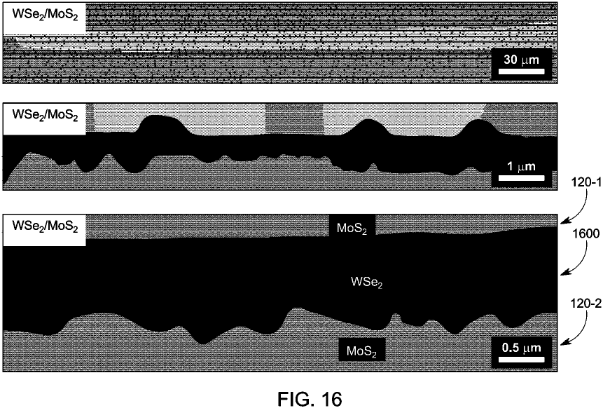

Because the LDE growth discussed in the previous embodiments is directed by the combination of (1) the ledge sites and (2) the surface-diffusion-limited pathway, which is intrinsic to the Ga₂O₃ substrates, its use is not limited to the MoS₂-Ga₂O₃ combination illustrated here. Instead, it could be generalized for producing various TMD nanoribbons, including n-(MoS₂), p-(WSe₂) and even lateral n-(MoS₂)-p-(WSe₂)-n-(MoS₂) junctions with precise single crystallinity, alignment and monolayer controls over a micro- to centimeter scale. While TMD nanoribbons with lateral heterostructures have been recently reported by vapour-liquid-solid growth, such a process only allows the growth of heterostructures with either different metals or chalcogen atoms, thus making it challenging for the creation of p-n heterostructures or even n-p-n multi-heterostructures. LDE WSe₂-MoS₂ lateral n-p-n multi-heterojunctions are achieved by growing WSe₂ nanoribbons 1600 first on β—Ga₂O₃ (100) substrate, followed by the edge epitaxy of MoS₂ nanoribbons 120-1 and 120-2 on both sides of the WSe₂ nanoribbon 1600, as shown in FIG. 16. Hyper-spectral PL mapping of relevant PL characteristics, including MoS₂ and WSe₂, in tandem with Raman and PL spectra (not shown), proves the successful in-plane growth of the n-type MoS₂ at both edges of the p-type WSe₂.

Devices based on atomically thin, single-crystal monolayers represent the extreme scenario for the future of low-power consumption electronics. The discovery of utilizing ledge-directed epitaxy, termed LDE herein, as an industry-compatible, scalable yet general platform offers designers and engineers a canvas that gives rise to libraries of 2D layered materials with a full spectrum of electronic properties. For example, hexagonal boron nitride (hBN) is an insulator and a wide-band-gap emitter. Graphene performs as an excellent conductor with a high carrier mobility. Transition metal dichalcogenides can serve as high on-off ratio semiconductors and for high quantum efficiency optical/optoelectronic applications. The low material cost and potentially simple production of the devices based on 2D layered materials are attractive for future green electronics. The lack of dangling bonds coupled with the defect free, singe-crystal basal plane makes it an ideal candidate for an effective coating for anti-fouling, satellite radiation, anticorrosion and filtration applications. Since these materials are covalently bonded monolayer, they possess high flexibility (bendability) and transparency, and are promising for flexible, light-weight (skin)electronic, sensor and optical device applications. Most critical components in modern electronics/optoelectronics can be redesigned and produced based on this new class of 2D layered materials, where the great ability to tune the band gap, band offset, carrier density, carrier polarity and switching characteristics provide unparalleled control over device properties and possibly new physical phenomena in data processing, wireless communications, and consumer electronics. The new electronics based on 2D layered materials are hence called “monolayer electronics.”

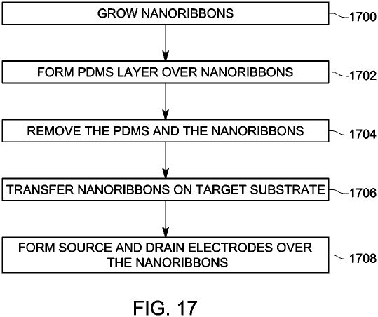

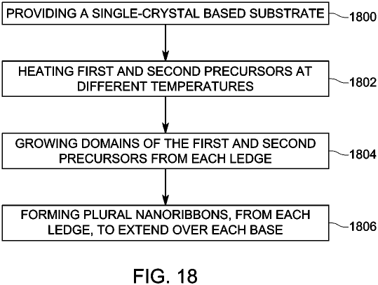

A method for making a nanoribbon based transistor is now discussed with regard to FIG. 17. Single-crystal MoS₂ and/or WSe₂ monolayer nanoribbons were grown in step 1700 on the β—Ga₂O₃ (100) substrate by conventional CVD in a horizontal hot-wall in furnace tube with two heating zones. More specifically, as illustrated in FIG. 18, the step 1700 includes a step 1800 of providing the single-crystal based substrate 100. In step 1802, high-purity S, Se, MoO₃ and WO₃ powders were used as the reaction precursors. The MoO₃ (WO₃) powder was placed in a ceramic boat and was put in the heating zone center of the furnace. The S (Se) powder was placed in a separate quartz boat at the upper stream side, and maintained at 140° C. (270° C.) during the reaction. The single-crystal β—Ga₂O₃ (100) substrate was placed at the downstream side, where the precursor vapors were brought to the substrates by Ar gas flowing at 30 torr for MoS₂, and an Ar/H2 gas mixture at 10 torr for WSe₂. The center heating zone was heated to 800° C. and kept there for 10 min for the growth of the MoS₂ domains 110 in step 1804, which resulted in the nanoribbons 120 in step 1806. For the growth of the WSe₂ nanoribbons, the furnace was heated to 900° C. and held for 15 min. Upon completion of the growth, the furnace was naturally cooled to room temperature.

After the CVD growth, the resulting MoS₂ nanoribbons on the β-Ga₂O₃ (100) substrate were transferred onto a substrate of interest, for example, Si substrate 1002 as shown in FIG. 10, via a PDMS-assisted approach. More specifically, a thin PDMS film 130 (see FIG. 1G) was placed in step 1702 on top of the MoS₂/β—Ga₂O₃. It is desired in this step to ensure conformal contact between the PDMS and the MoS₂/β—Ga₂O₃. Next, the PDMS/MoS₂/β—Ga₂O₃ stacked film was soaked in 1 M KOH for 5 min at room temperature, followed by rinsing the sample with a large amount of deionized water. The PDMS/MoS₂ stacked film was slowly peeled off in step 1704 from the β—Ga₂O₃ and then placed in step 1706 on the target substrate 1002. The sample was kept in a vacuum for 30 min to make sure of adhesion between the MoS₂ nanoribbons 120 and the target substrate 1002 or any other layer formed on top of the substrate 1002. Residual water droplets were dried under a constant N₂ flow. Finally, the PDMS layer 130 was peeled off, leaving behind the MoS₂ nanoribbons 120 on the target substrate 1002.

In one embodiment, as shown in FIG. 10, the monolayer of MoS₂ nanoribbons 120 grown on the β—Ga₂O₃ (100) substrate 100 was transferred in step 1706 on a 15 nm thick layer of HfO₂ 1004, which was deposited on heavily doped silicon layer 1002, via atomic layer deposition, which acts as a gate insulator. A single-crystalline hBN monolayer 1006 was detached from the Cu (111) and sapphire substrate by electrochemical delamination and then transferred onto the HfO₂/Si layers via a combination of thermal release tape (TRT) and poly (methyl methacrylate) (PMMA). The TRT can be released by annealing the TRT/PMMA/hBN/HfO₂/Si-stacked films on a hotplate at 180° C. The PMMA film was thoroughly removed via iteratively immersing the sample in a hot acetone bath for 40 min, leaving behind the hBN/HfO₂/Si-stacked substrate. After transferring the MoS₂ nanoribbons 120, the resulting MoS₂ nanoribbons stacked on hBN/HfO₂/Si were placed in a vacuum chamber under a pressure of 10⁻⁶ torr for 12 h. Owing to the global alignment of the LDE-grown MoS₂ nanoribbons 120, which provides far fewer constraints for the effective fabrication of the FET 1000, electron-beam lithography emerges as the reliable method for producing the patterns of metal electrodes 1010 and 1012 in step 1708, which are made of nickel (Ni, 20 nm) and gold (Au, 50 nm) for electrical testing. More than one hundred single-nanoribbon FETs were produced by this method, and all were tested to confirm the electrical output performance of the transistors. The high electrical performance is due to the uniform, self-aligned and tunable distribution of the MoS₂ nanoribbons 120 over the entire area of the β—Ga₂O₃ (100) substrate (having a size of about 1 cm × 1.5 cm).

The disclosed embodiments provide nanoribbons and nanoribbons based electronic devices, where the nanoribbons are formed by ledge-directed epitaxy, which makes the nanoribbons to be continuous, self-aligned, single-crystalline, 2D materials. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

Hung, Y. H. et al. Scalable patterning of MoS2 nanoribbons by micromolding in capillaries. ACS Appl. Mater. Interfaces 8, 20993-21001 (2016).

Li, S. et al. Vapour-liquid-solid growth of monolayer MoS2 nanoribbons. Nat. Mater. 17, 535-542 (2018).

Chowdhury, T. et al. Substrate-directed synthesis of MoS2 nanocrystals with tunable dimensionality and optical properties. Nat. Nanotechnol. 15, 29-34 (2020).

Chen, T. A. et al. Wafer-scale single-crystal hexagonal boron nitride monolayers on Cu (111). Nature 579, 219-223 (2020).

Zhang, X. et al. Defect-controlled nucleation and orientation of WSe2 on hBN: a route to single-crystal epitaxial monolayers. ACS Nano 13, 3341-3352 (2019).

What is claimed is:

1. A transistor comprising:
a substrate;
an oxide layer located over the substrate;
a nanoribbon located over the oxide layer; and
first and second electrodes formed around the nanoribbon,
wherein the nanoribbon has an aspect ratio of a length over a thickness equal to or larger than 5,000.

2. The transistor of claim 1, further comprising:
a single-crystal hBN monolayer film provided between the oxide layer and the nanoribbon.

3. The transistor of claim 1, wherein the nanoribbon has a single crystalline structure.

4. The transistor of claim 1, wherein the nanoribbon includes plural nanoribbons.

5. The transistor of claim 1, wherein the nanoribbon includes MoS₂, the substrate includes silicon, and the oxide layer includes HfO₂.

6. The transistor of claim 1, further comprising:
a gate electrode formed on the substrate.

7. The transistor of claim 1, wherein the nanoribbon is continuous.

8. A method for making nanoribbons, comprising:
providing a single-crystal based substrate that exhibits cleavage, wherein the substrate has plural ledges and plural bases that extend between the plural ledges;
heating first and second precursors at different temperatures;
growing domains made of the first and second precursors, starting from each ledge of the plural ledges, and extending over the plural bases; and
forming plural nanoribbons, each nanoribbon of the plural nanoribbons extending from a single ledge over one or two bases,
wherein the nanoribbon is continuous, single-crystalline, and self-aligned.

9. The method of claim 8, wherein the single-crystal based substrate is a β—Ga₂O₃ substrate.

10. The method of claim 9, wherein the plural ledges include different first and second ledges, the first ledge extends in a plane and the second ledge extends in a plane, while the bases extend in a plane.

11. The method of claim 10, wherein each nanoribbon is associated with a corresponding ledge.

12. The method of claim 10, wherein the first precursor is MoO₃ and the second precursor is S, so that the plural nanoribbons are made of MoS₂.

13. The method of claim 10, wherein the first precursor is WO₃ and the second precursor is Se, so that the plural nanoribbons are made of WSe₂.

14. The method of claim 8, wherein each nanoribbon of the plural nanoribbons has an aspect ratio of a length over a thickness equal to or larger than 5,000.

15. The method of claim 8, further comprising:
forming a layer of PDMS on top of the plural nanoribbons;
peeling off the layer of PDMS together with the plural nanoribbons;
placing the layer of PDMS with the plural nanoribbons on a target substrate; and
removing the layer of PDMS while the plural nanoribbons remain on the target substrate.

16. The method of claim 15, further comprising:
removing a top surface of the single-crystal based substrate by cleavage; and
repeating the steps of heating, growing and forming.

17. A method for transferring a nanoribbon from a first substrate to a second substrate, the method comprising:
growing plural nanoribbons on a single-crystal based substrate, which exhibits cleavage, wherein the substrate has plural ledges and plural bases that extend between the plural ledges;
forming a layer of polydimethylsiloxane over the nanoribbons;
removing the layer of polydimethylsiloxane and the nanoribbons from the single-crystal based substrate;
transferring the layer of polydimethylsiloxane and the nanoribbons onto a target substrate; and
forming source and drain electrodes over the nanoribbons to form an electronic device.

18. The method of claim 17, wherein the electronic device is a transistor, the single-crystal based substrate is β—Ga₂O₃, the target substrate is Si, and the nanoribbons are MoS₂.

19. The method of claim 17, wherein the electronic device is a transistor, the single-crystal based substrate is β—Ga₂O₃, the target substrate is Si, and the nanoribbons are WSe₂.

20. The method of claim 17, wherein the plural ledges include different first and second ledges, the first ledge extends in a plane and the second ledge extends in a plane, while the bases extend in a plane.
